(19) United States
(12) Patent Application Publication
(10) Pub. No.: US 2026/0279467 A1
(43) Pub. Date: Sep. 17, 2026

(54) SEMICONDUCTOR DEVICE AND CONTROL METHOD THEREOF

(71) Applicant: Kioxia Corporation, Tokyo (JP)

(72) Inventor: Masashi NIIMURA, Yokohama Kanagawa (JP)

(21) Appl. No.: 19/326,448

(22) Filed: Sep. 11, 2025

(30) Foreign Application Priority Data
Mar. 14, 2025 (JP) 2025-041772

(51) Int. Cl. G11C 16/32; G05F 1/46

(52) U.S. Cl. CPC G11C 16/32; G05F 1/463

(57) ABSTRACT

A semiconductor device that can realize preferable temperature control, and a control method thereof are provided. A semiconductor device that is operable based on a signal from an external device includes, on a chip, a memory cell array, a temperature sensor configured to detect a temperature in the semiconductor device, and a temperature control circuit. The temperature control circuit is configured to control signal processing for operating the memory cell array so as to reduce heat generation by the semiconductor device based on the temperature detected by the temperature sensor.

### CROSS-REFERENCE TO RELATED APPLICATIONS

This application is based upon and claims the benefit of priority from Japanese Patent Application No. 2025-041772, filed Mar. 14, 2025, the entire contents of which are incorporated herein by reference.

### FIELD

Embodiments described herein relate generally to a semiconductor device and a control method thereof.

### BACKGROUND

There are various problems with controlling a temperature in a semiconductor device. For example, when a manufacturer of a semiconductor device and a manufacturer of an external component that controls the temperature in the semiconductor device are different, it is difficult for the manufacturer of the external component to design a preferable temperature control mechanism.

### BRIEF DESCRIPTION OF THE DRAWINGS

FIG. 1 is a block diagram showing a configuration of a memory system according to a first embodiment.

FIG. 2 is a block diagram showing a configuration of a NAND memory of the first embodiment.

FIG. 3 is a schematic diagram showing a configuration of the memory system according to the first embodiment.

FIG. 4 is a block diagram showing a configuration of a control circuit of the first embodiment.

FIG. 5 is a block diagram showing a configuration of a control circuit of a second embodiment.

FIG. 6 is a schematic diagram showing a configuration of a memory system according to a third embodiment.

### DETAILED DESCRIPTION

There are provided a semiconductor device that can realize preferable temperature control, and a control method thereof.

In general, according to an embodiment, a semiconductor device that is operable based on a signal from an external device includes, on a chip, a memory cell array, a temperature sensor configured to detect a temperature in the semiconductor device, and a temperature control circuit. The temperature control circuit is configured to control signal processing for operating the memory cell array so as to reduce heat generation by the semiconductor device based on the temperature detected by the temperature sensor.

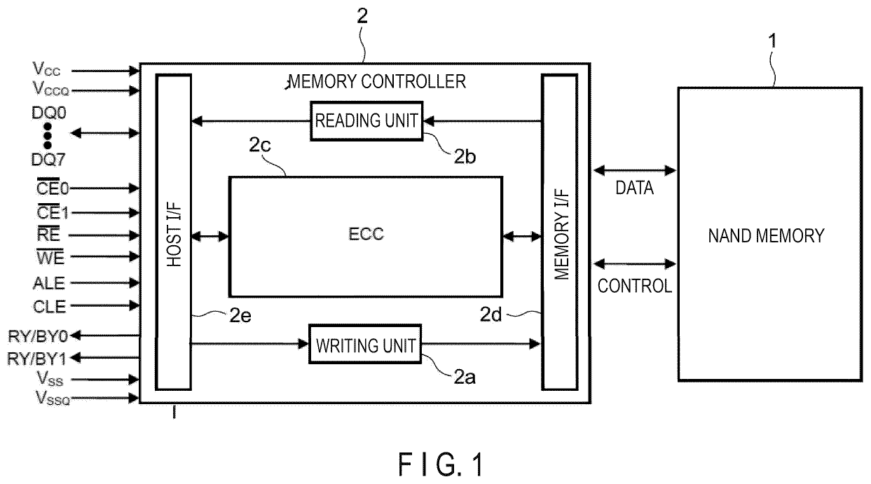

Hereafter, embodiments of the present invention will be described with reference to the drawings. In FIG. 1 to FIG. 6, the same configurations are given the same signs, and their duplicate description is omitted.

### First Embodiment

FIG. 1 is a block diagram showing a configuration of a memory system according to a first embodiment.

The memory system according to the present embodiment includes a NAND memory 1 and a memory controller 2. The NAND memory 1 is an example of each of the semiconductor device and a semiconductor memory. The memory controller 2 is an example of the external device. The memory controller 2 includes a writing unit 2a, a reading unit 2b, an ECC (Error Correcting Code) circuit 2c, a memory I/F (Interface) controller 2d, and a host I/F controller 2e.

The NAND memory 1 is a nonvolatile semiconductor storage device including a plurality of memory cells. The memory controller 2 is an external component for the NAND memory 1, and is electrically connected to the NAND memory 1. By outputting various signals to the NAND memory 1, the memory controller 2 controls various operations of the NAND memory 1. The NAND memory 1 of the present embodiment can operate based on signals from the memory controller 2.

The writing unit 2a controls writing of data into the NAND memory 1. The reading unit 2b controls reading of data from the NAND memory 1. The ECC circuit 2c performs error correction processing of data. When data is written into the NAND memory 1, the ECC circuit 2c gives the written data an error correction code. When data is read from the NAND memory 1, the ECC circuit 2c corrects an error in the read data based on the error correction code in the read data.

The memory I/F controller 2d manages an interface between the NAND memory 1 and the memory controller 2. The writing unit 2a writes data into the NAND memory 1 via the memory I/F controller 2d. The reading unit 2b reads data from the NAND memory 1 via the memory I/F controller 2d.

The host I/F controller 2e manages an interface between the memory controller 2 and a host apparatus (not shown). The writing unit 2a receives a write request from the host apparatus via the host I/F controller 2e, and in response to the write request, writes data into the NAND memory 1. The reading unit 2b receives a read request from the host apparatus via the host I/F controller 2e, and in response to the read request, reads data from the NAND memory 1.

For example, the host apparatus is an information processing apparatus such as a PC (Personal Computer). The memory system according to the present embodiment functions as an external storage apparatus of the host apparatus, and specifically, functions as a storage of the host apparatus. The memory system according to the present embodiment is, for example, an SSD (Solid State Drive).

As examples of signals between the memory system according to the present embodiment and the host apparatus, FIG. 1 shows a signal DQ, a chip enable signal/CE, a read enable signal/RE, a write enable signal/WE, an address latch enable signal ALE, a command latch enable signal CLE, and a ready/busy signal RY/BY. As examples of voltages supplied to the memory system of the present embodiment, FIG. 1 further shows a power supply voltage VCC, a power supply voltage VCCQ, a ground voltage VSS, and a ground voltage VSSQ.

The chip enable signal/CE is a signal for selecting the NAND memory 1 (NAND chip). The read enable signal/RE is a signal that enables reading of data. The write enable signal/WE is a signal that enables writing of data. The address latch enable signal ALE is a signal for causing an address register to latch an address transmitted as the signal DQ. The command latch enable signal CLE is a signal for causing a command register to latch a command transmitted as the signal DQ. The ready/busy signal RY/BY is a signal indicating that the NAND memory 1 is in a ready state of being able to accept the command or is in a busy state of being unable to accept the command.

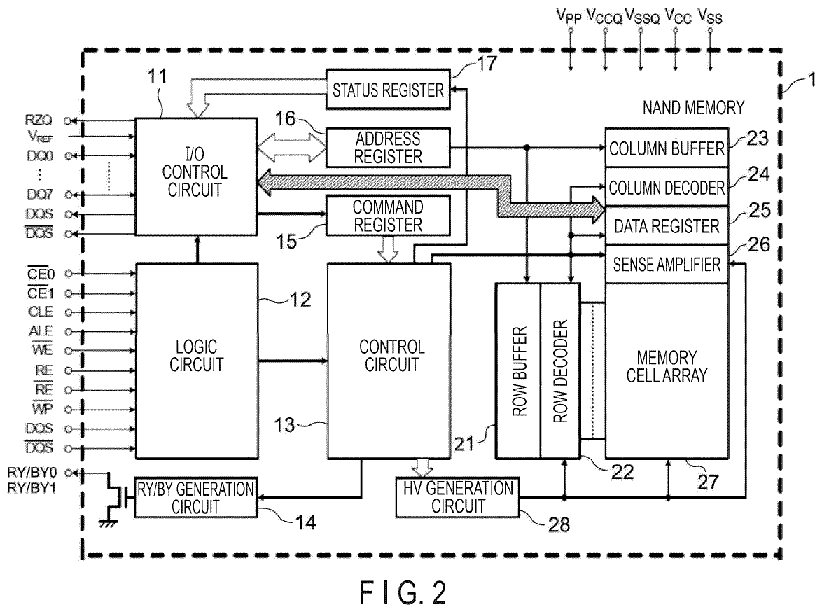

FIG. 2 is a block diagram showing a configuration of the NAND memory 1 of the first embodiment.

The NAND memory 1 of the present embodiment includes an I/O (Input/Output) control circuit 11, a logic circuit 12, a control circuit 13, an RY/BY (Ready/Busy) generation circuit 14, a command register 15, an address register 16, a status register 17, a row buffer 21, a row decoder 22, a column buffer 23, a column decoder 24, a data register 25, a sense amplifier 26, a memory cell array 27, and an HV (High Voltage) generation circuit 28. As examples of voltages supplied to the NAND memory 1 of the present embodiment, FIG. 2 shows the power supply voltage VCC, the power supply voltage VCCQ, a power supply voltage VPP, the ground voltage VSS, and the ground voltage VSSQ.

The I/O control circuit 11 is a buffer circuit that processes input signals to the NAND memory 1 and output signals from the NAND memory 1. Commands, addresses, and data latched by the I/O control circuit 11 are allocated to the command register 15, the address register 16, and the data register 25, respectively. As examples of signals handled by the I/O control circuit 11, FIG. 2 shows the signal DQ, a signal RZQ, a reference voltage VREF, data strobe signals DQS and/DQS.

The logic circuit 12 processes control signals to the NAND memory 1. Specifically, the logic circuit 12 controls the aforementioned allocation by the I/O control circuit 11 based on the control signals to the NAND memory 1. Furthermore, the logic circuit 12 transfers the control signals to the control circuit 13. As examples of control signals handled by the logic circuit 12, FIG. 2 shows the chip enable signal/CE, the read enable signals RE and/RE, the write enable signal/WE, the address latch enable signal ALE, the command latch enable signal CLE, a write protect signal/WP, and the data strobe signals DQS and/DQS. The write protect signal/WP is a signal that prohibits writing and erasing of data.

The control circuit 13 controls the NAND memory 1. Specifically, the control circuit 13 controls various operations of the NAND memory 1 based on the control signals transferred from the logic circuit 12. An operation mode of the control circuit 13 varies, for example, by the state of the control circuit 13 changing in response to the control signals.

The RY/BY generation circuit 14 outputs the ready/busy signal RY/BY. When the NAND memory 1 is in the ready state of being able to accept a command, the RY/BY generation circuit 14 outputs, as the ready/busy signal RY/BY, a signal indicating that the NAND memory 1 is in the ready state. On the other hand, when the NAND memory 1 is in the busy state of being unable to accept a command, the RY/BY generation circuit 14 outputs, as the ready/busy signal RY/BY, a signal indicating that the NAND memory 1 is in the busy state.

The command register 15 is a register that stores the command. The command stored in the command register 15 is read by the control circuit 13.

The address register 16 is a register that stores the address. The address stored in the address register 16 is read by the control circuit 13, the row buffer 21, and the column buffer 23.

The status register 17 is a register that stores a status of a read operation, a write operation, an erase operation, or the like. The status register 17 is used for notifying the memory controller 2 of the completion of each of these operations. The status stored in the status register 17 is read by the control circuit 13.

The row buffer 21 and the row decoder 22 control word lines in the memory cell array 27. Specifically, based on a row address read from the address register 16 by the row buffer 21, the row decoder 22 applies a voltage to a word line in the memory cell array 27.

The column buffer 23 and the column decoder 24 control latch circuits in the data register 25. Specifically, based on a column address read from the address register 16 by the column buffer 23, the column decoder 24 selects a latch circuit in the data register 25.

The data register 25 is a register that stores data. Specifically, the data register 25 stores data from the I/O control circuit 11 and data from the sense amplifier 26.

The sense amplifier 26 is an amplifier for bit lines in the memory cell array 27. Specifically, the sense amplifier 26 senses data read on bit lines in the memory cell array 27.

The memory cell array 27 includes a plurality of memory cells arranged into an array. For example, the NAND memory 1 of the present embodiment is a three-dimensional NAND memory in which these memory cells are arranged into a three-dimensional array.

The HV generation circuit 28 generates voltages required for the read operation, the write operation, the erase operation, and the like. The voltages generated by the HV generation circuit 28 are supplied to the memory cell array 27, the sense amplifier 26, and the row decoder 22.

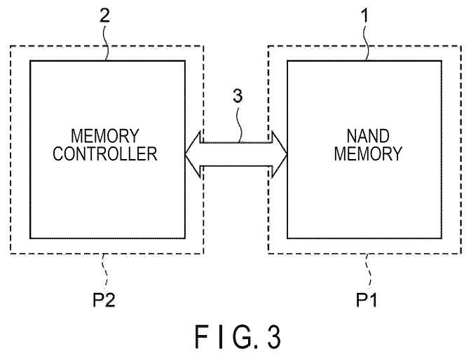

FIG. 3 is a schematic diagram showing a configuration of the memory system according to the first embodiment.

In the memory system according to the present embodiment, the NAND memory 1 is included in a semiconductor package P1, and the memory controller 2 is included in a semiconductor package P2 different from the semiconductor package P1. FIG. 3 further shows a communication path 3 that electrically connects the NAND memory 1 and the memory controller 2. Notably, while the NAND memory 1 and the memory controller 2 are included in the different semiconductor packages in the present embodiment, they may be included in the same semiconductor package as described below.

In the present embodiment, the NAND memory 1 is formed of one semiconductor chip (NAND chip), the memory controller 2 is formed of another semiconductor chip (controller chip), and these semiconductor chips are included in the different semiconductor packages P1 and P2. The NAND memory 1 of the present embodiment is called a Raw NAND meaning a NAND device that is divided into the NAND memory 1 and the memory controller 2. In the memory system of the present embodiment, the NAND memory 1 includes the memory cell array 27, and the memory controller 2 has a function of controlling the NAND memory 1 and a function of mediating the NAND memory 1 and the host apparatus.

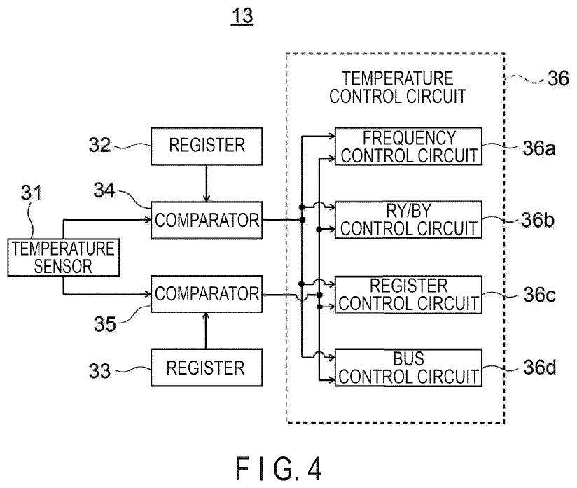

FIG. 4 is a block diagram showing a configuration of the control circuit 13 of the first embodiment.

The control circuit 13 of the present embodiment includes a temperature sensor 31, a register 32, a register 33, a comparator 34, a comparator 35, a temperature control circuit 36. The registers 32 and 33 are examples of first and second registers, respectively. The comparators 34 and 35 are examples of first and second comparators, respectively. The temperature control circuit 36 includes a frequency control circuit 36a, an RY/BY control circuit 36b, a register control circuit 36c, and a bus control circuit 36d.

The temperature sensor 31 detects a temperature in the NAND memory 1. Furthermore, the temperature sensor 31 outputs a signal indicating the detected temperature to the comparators 34 and 35.

There is concern of malfunction of the NAND memory 1 when it is exposed for a long time to a high temperature. Therefore, based on the temperature detected by the temperature sensor 31, the control circuit 13 controls the temperature in the NAND memory 1. Specifically, when the temperature detected by the temperature sensor 31 is high, the control circuit 13 controls an operation of the NAND memory 1 such that the amount of heat generated per unit time in the NAND memory 1 decreases. For example, by reducing a current consumption in the NAND memory 1, the amount of heat generated in the NAND memory 1 is reduced. As a result, the temperature in the NAND memory 1 decreases. Such control is performed by the temperature control circuit 36 as described below. Such control is called thermal throttling.

The register 32 holds a setting temperature (enable temperature) for turning on control of the temperature in the NAND memory 1. In the present embodiment, the setting temperature may be stored in the register 32 by default before the NAND memory 1 is sold, or the setting temperature may be stored in the register 32 by a user of the NAND memory 1 after the NAND memory 1 is sold. The setting temperature in the register 32 is an example of a first setting temperature. Furthermore, the register 32 outputs a signal indicating the setting temperature in the register 32 to the comparator 34.

The setting temperature in the register 32 is desirably set to be higher than a room temperature, and is desirably set to about 90° C., for example. There is concern of malfunction of the NAND memory 1 when it is exposed for a long time to a temperature higher than 85° C., for example. Therefore, the setting temperature in the register 32 is desirably set to 90° C., higher than 85° C., in order to detect that a temperature of NAND memory 1 is higher than 85° C., namely, that there occurs an event to cause malfunction of the NAND memory 1. In the present embodiment, by setting the setting temperature in the register 32 to a temperature that is not 85° C. but is higher than 85° C., it is possible to restrain the control of the temperature in the NAND memory 1 from being excessively turned on. Furthermore, by setting the setting temperature in the register 32 to the temperature that is close to 85° C., it is possible to restrain timing when the control of the temperature in the NAND memory 1 is turned on from being excessively late.

The register 33 holds a setting temperature (disable temperature) for turning off the control of the temperature in the NAND memory 1. In the present embodiment, the setting temperature may be stored in the register 33 by default before the NAND memory 1 is sold, or the setting temperature may be stored in the register 33 by a user of the NAND memory 1 after the NAND memory 1 is sold. The setting temperature in the register 33 is an example of a second setting temperature. Furthermore, the register 33 outputs a signal indicating the setting temperature in the register 33 to the comparator 35.

The setting temperature in the register 33 is desirably set to be higher than the room temperature, and is desirably set to 70 to 75° C., for example. As described above, there is concern of malfunction of the NAND memory 1 when it is exposed for a long time to a temperature higher than 85° C., for example. Therefore, the setting temperature in the register 33 is desirably set to 70 to 75° C., lower than 85° C., in order to detect that the temperature of the NAND memory 1 is lower than 85° C., namely, that there has been removed the event to cause malfunction of the NAND memory 1. In the present embodiment, by setting the setting temperature in the register 33 to a temperature that is not 85° C. but is lower than 85° C., it is possible to restrain the control of the temperature in the NAND memory 1 from being excessively turned off. Furthermore, by setting the setting temperature in the register 33 to the temperature that is close to 85° C., it is possible to restrain timing when the control of the temperature in the NAND memory 1 is turned off from being excessively late. For the reasons above, in the present embodiment, the setting temperature in the register 33 is desirably set to be lower than the setting temperature in the register 32.

By comparing the signal from the temperature sensor 31 and the signal from the register 32, the comparator 34 compares the temperature detected by the temperature sensor 31 and the setting temperature held by the register 32. Furthermore, the comparator 34 outputs a signal indicating the comparison result between the temperature of the former and the setting temperature of the latter to the temperature control circuit 36. The relevant signal is an example of a first signal. In the present embodiment, when the detected temperature of the temperature sensor 31 is lower than the setting temperature of the register 32, the signal becomes High, and when the detected temperature of the temperature sensor 31 is higher than the setting temperature of the register 32, the signal becomes Low.

By comparing the signal from the temperature sensor 31 and the signal from the register 33, the comparator 35 compares the temperature detected by the temperature sensor 31 and the setting temperature held by the register 33. Furthermore, the comparator 35 outputs a signal indicating the comparison result between the temperature of the former and the setting temperature of the latter to the temperature control circuit 36. The relevant signal is an example of a second signal. In the present embodiment, when the detected temperature of the temperature sensor 31 is higher than the setting temperature of the register 33, the signal becomes High, and when the detected temperature of the temperature sensor 31 is lower than the setting temperature of the register 33, the signal becomes Low.

The temperature control circuit 36 can take two states of an enabled state (ON-state) and a disabled state (OFF-state). The temperature control circuit 36 in the enabled state operates to control the temperature in the NAND memory 1 by controlling the operation of the NAND memory 1 (e.g., signal processing for operating the memory cell array 27). Thereby, the temperature in the NAND memory 1 can be reduced. On the other hand, the temperature control circuit 36 in the disabled state suspends the control of the temperature in the NAND memory 1.

The temperature control circuit 36 receives, from the comparator 34, the output signal indicating the comparison result between the detected temperature of the temperature sensor 31 and the setting temperature of the register 32, and receives, from the comparator 35, the output signal indicating the comparison result between the detected temperature of the temperature sensor 31 and the setting temperature of the register 33. The temperature control circuit 36 controls the temperature in the NAND memory 1 based on these output signals.

Immediately after electric power is applied to the NAND memory 1, the temperature control circuit 36 generally takes the disabled state. The reason is that, immediately after electric power is applied to the NAND memory 1, the temperature in the NAND memory 1 is a room temperature and is lower than the setting temperatures of the registers 32 and 33.

After electric power is applied to the NAND memory 1, the temperature in the NAND memory 1 rises, and there is a case where the detected temperature of the temperature sensor 31 becomes higher than the setting temperature of the register 32. In this case, the output signal of the comparator 34 changes from High to Low to indicate that the detected temperature of the temperature sensor 31 is higher than the setting temperature of the register 32. The temperature control circuit 36 takes the enabled state in response to this output signal, and turns on the control of the temperature in the NAND memory 1. As above, in the NAND memory 1, temperature control by the temperature control circuit 36 is started.

When the temperature control circuit 36 is in the enabled state, the control of the temperature in the NAND memory 1 is kept turned on, and the temperature control by the temperature control circuit 36 is continued. Thereby, the temperature in the NAND memory 1 decreases, and the detected temperature of the temperature sensor 31 becomes lower than the setting temperature of the register 33. In this case, the output signal of the comparator 35 changes from High to Low to indicate that the detected temperature of the temperature sensor 31 is lower than the setting temperature of the register 33. The temperature control circuit 36 returns to the disabled state in response to this output signal, and turns off the control of the temperature in the NAND memory 1. As above, in the NAND memory 1, the temperature control by the temperature control circuit 36 is ended.

After that, the operation in which the temperature control circuit 36 takes the enabled state and the operation in which the temperature control circuit 36 returns to the disabled state are repeated in the NAND memory 1 until the application of electric power to the NAND memory 1 is ended.

Next, the frequency control circuit 36a, the RY/BY control circuit 36b, the register control circuit 36c, and the bus control circuit 36d in the temperature control circuit 36 are described. The frequency control circuit 36a, the RY/BY control circuit 36b, the register control circuit 36c, and the bus control circuit 36d in the temperature control circuit 36 control the temperature in the NAND memory 1 when the temperature control circuit 36 is in the enabled state. Thereby, the amount of heat generated in the NAND memory 1 can be reduced, and the temperature in the NAND memory 1 can be reduced.

The frequency control circuit 36a controls the temperature in the NAND memory 1 by controlling a frequency of a clock signal in the NAND memory 1 (clock frequency). Specifically, the frequency control circuit 36a reduces the temperature in the NAND memory 1 by reducing the clock frequency. In the present embodiment, by setting the clock frequency in the enabled state to be lower than the clock frequency in the disabled state, the operation of the NAND memory 1 in the enable state can be made slow. Thereby, the temperature in the NAND memory 1 in the enabled state can be simply reduced.

The RY/BY control circuit 36b controls the temperature in the NAND memory 1 by controlling a state of the NAND memory 1. Specifically, by delaying timing for switching the state of the NAND memory 1 from a busy state to a ready state, the RY/BY control circuit 36b reduces the temperature in the NAND memory 1. In the present embodiment, the operation of the NAND memory 1 in the enabled state can be made slow by setting a time required for the aforementioned switching in the enabled state to be longer than a time required for the aforementioned switching in the disabled state. Thereby, the temperature in the NAND memory 1 in the enabled state can be effectively reduced. The control by the RY/BY control circuit 36b is performed, for example, in data writing into the NAND memory 1.

The register control circuit 36c controls the temperature in the NAND memory 1 by controlling a register for information regarding the state of the NAND memory 1. Specifically, the register control circuit 36c reduces the temperature in the NAND memory 1 by delaying, when the state of the NAND memory 1 is switched from the busy state to the ready state, timing for storing information regarding the relevant switching in the status register 17. In the present embodiment, the operation of the NAND memory 1 in the enabled state can be made slow by setting a time required for the aforementioned storing in the enabled state to be longer than a time required for the aforementioned storing in the disabled state. Thereby, the temperature in the NAND memory 1 in the enabled state can be effectively reduced. The control by the register control circuit 36c is performed, for example, in data writing into the NAND memory 1.

The bus control circuit 36d controls the temperature in the NAND memory 1 by controlling a bus of the NAND memory 1. Specifically, the bus control circuit 36d reduces the temperature in the NAND memory 1 by reducing a communication speed on the bus (Example: 2.4 Gbps→1.2 Gbps). In the present embodiment, the operation of the NAND memory 1 in the enabled state can be made slow by setting a communication speed in the enabled state to be lower than a communication speed in the disabled state. Thereby, the temperature in the NAND memory 1 in the enabled state can be more effectively reduced. The control by the bus control circuit 36d is performed, for example, in data reading from the NAND memory 1. Notably, the aforementioned bus may be a bus in the NAND memory 1, or may be a bus between the NAND memory 1 and the memory controller 2.

Notably, as to the four blocks of the frequency control circuit 36a, the RY/BY control circuit 36b, the register control circuit 36c, and the bus control circuit 36d, the temperature control circuit 36 in the enabled state may control the temperature in the NAND memory 1 using all of these blocks, or may control the temperature in the NAND memory 1 only using a part of these blocks. For example, in data writing into the NAND memory 1, the temperature control circuit 36 may control the temperature in the NAND memory 1 using only the RY/BY control circuit 36b and the register control circuit 36c. Using more of these blocks leads to an advantage, for example, of being able to reduce the temperature in the NAND memory 1 more effectively. On the other hand, using a smaller number of these blocks leads to an advantage, for example, of being able to simplify control of these blocks. Notably, while the temperature control circuit 36 includes these four blocks in the present embodiment, the number of such blocks in the temperature control circuit 36 may be other than four.

Next, continuously with reference to FIG. 4, an exemplary operation of the control circuit 13 of the present embodiment is described.

When electric power is applied to the NAND memory 1, coded temperatures are set into the registers 32 and 33 based on a SetFeature command. The codes of the temperatures set in the registers 32 and 33 correspond to the binary code of the temperature in the temperature sensor 31. In the present embodiment, default temperature values in a ROM fuse provided in the NAND memory 1 are set into the registers 32 and 33.

When the NAND memory 1 continues to be operated, the temperature in the NAND memory 1 is rising under the influence of the peripheral environment and the conditions of the NAND memory 1. During the operation of the NAND memory 1, the comparators 34 and 35 are comparing the detected temperature of the temperature sensor 31 with the setting temperatures of the registers 32 and 33, respectively, at constant intervals in synchronization with an internal clock signal of the NAND memory 1. The temperature control circuit 36 changes from the disabled state to the enabled state at the time point when the detected temperature of the temperature sensor 31 exceeds the setting temperature of the register 32. As a result, the NAND memory 1 is brought into a temperature control mode, which is different from a normal operation mode, and processing of limiting power consumption in the NAND memory 1 is started in the temperature control circuit 36.

The temperature control circuit 36 in the enabled state reduces the temperature in the NAND memory 1 by limiting the power consumption in the NAND memory 1. Also in the case where the temperature control circuit 36 is in the enabled state, the comparators 34 and 35 are comparing the detected temperature of the temperature sensor 31 with the setting temperatures of the registers 32 and 33, respectively, at constant intervals in synchronization with the aforementioned internal clock signal. The temperature control circuit 36 changes from the enabled state to the disabled state at the time point when the detected temperature of the temperature sensor 31 goes below the setting temperature of the register 33. As a result, the NAND memory 1 is returned to the normal operation mode, and the processing of limiting the power consumption in the NAND memory 1 is ended in the temperature control circuit 36.

Next, continuously with reference to FIG. 4, advantages of the control circuit 13 of the present embodiment are described.

The memory system according to the present embodiment controls the temperature in the NAND memory 1 with the temperature control mechanism shown in FIG. 4. Thereby, failure such as malfunction of the NAND memory 1 can be restrained.

In addition, the memory system according to the present embodiment includes the temperature control mechanism (FIG. 4) controlling the temperature in the NAND memory 1, in the NAND memory 1, not in the memory controller 2. Thereby, the control of the temperature in the NAND memory 1 can be done only within the NAND memory 1, and a load of information processing on the memory controller 2 can be reduced.

In general, the memory controller 2 consumes a large amount of electric power. According to the present embodiment, the power consumption of the memory controller 2 can be reduced by providing the temperature control mechanism which controls the temperature in the NAND memory 1, in the NAND memory 1, not in the memory controller 2.

There is a case where a manufacturer of the NAND memory 1 and a manufacturer of the memory controller 2 are different from each other in the present embodiment. In this case, if a temperature control mechanism that controls the temperature in the NAND memory 1 is to be provided in the memory controller 2, a problem is difficulty of the manufacturer of the memory controller 2 in designing a preferable temperature control mechanism. On the other hand, according to the present embodiment, such a problem can be prevented by providing, in the NAND memory 1, the temperature control mechanism which controls the temperature in the NAND memory 1. The situation where the manufacturer of the NAND memory 1 and the manufacturer of the memory controller 2 are different arises, for example, in the case where the memory system of the present embodiment is an SSD, or the similar case. In this case, the NAND memory 1 and the memory controller 2 are generally housed in different semiconductor packages (see FIG. 3).

As above, according to the present embodiment, preferable temperature control for the NAND memory 1 can be realized.

### Second Embodiment

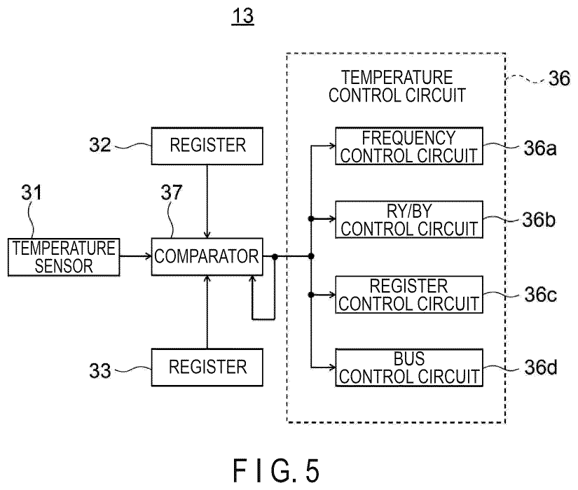

FIG. 5 is a block diagram showing a configuration of the control circuit 13 of a second embodiment.

The control circuit 13 of the present embodiment (FIG. 5) has the similar configuration to that of the control circuit 13 of the first embodiment (FIG. 4). It is noted, however, that the control circuit 13 of the present embodiment includes a comparator 37 in place of the comparators 34 and 35.

When the temperature control circuit 36 is in the disabled state, the comparator 37 also takes a disabled state. The comparator 37 in the disabled state compares the detected temperature of the temperature sensor 31 and the setting temperature of the register 32 by comparing the signal from the temperature sensor 31 and the signal from the register 32. Furthermore, the comparator 37 outputs the signal indicating the comparison result between the detected temperature of the temperature sensor 31 and the setting temperature of the register 32 to the temperature control circuit 36. In the present embodiment, as with the first embodiment, when the detected temperature of the temperature sensor 31 is lower than the setting temperature of the register 32, the output signal of the comparator 37 becomes High, and when the detected temperature of the temperature sensor 31 is higher than the setting temperature of the register 32, the output signal of the comparator 37 becomes Low. The temperature control circuit 36 having received this output signal operates as with the temperature control circuit 36 of the first embodiment. Specifically, when the output signal has changed from Low to High, the temperature control circuit 36 starts the control of the temperature in the NAND memory 1.

Moreover, when the temperature control circuit 36 is in the enabled state, the comparator 37 also takes an enabled state. The comparator 37 in the enabled state compares the detected temperature of the temperature sensor 31 and the setting temperature of the register 33 by comparing the signal from the temperature sensor 31 and the signal from the register 33. Furthermore, the comparator 37 outputs the signal indicating the comparison result between the detected temperature of the temperature sensor 31 and the setting temperature of the register 33 to the temperature control circuit 36. In the present embodiment, as with the first embodiment, when the detected temperature of the temperature sensor 31 is higher than the setting temperature of the register 33, the output signal of the comparator 37 becomes High, and when the detected temperature of the temperature sensor 31 is lower than the setting temperature of the register 33, the output signal of the comparator 37 becomes Low. The temperature control circuit 36 having received this output signal operates as with the temperature control circuit 36 of the first embodiment. Specifically, when the output signal has changed from Low to High, the temperature control circuit 36 ends the control of the temperature in the NAND memory 1.

In the present embodiment, the output signal of the comparator 37 is input (fed back) to the comparator 37. For example, in timing when the output signal of the comparator 37 changes from Low to High, the state of the comparator 37 changes from the disabled state to the enabled state, or from the enabled state to the disabled state. Thereby, the comparator 37 can also be brought into the disabled state when the temperature control circuit 36 is in the disabled state, and the comparator 37 can also be brought into the enabled state when the temperature control circuit 36 is in the enabled state.

According to the present embodiment, as with the first embodiment, preferable temperature control for the NAND memory 1 can be realized.

### Third Embodiment

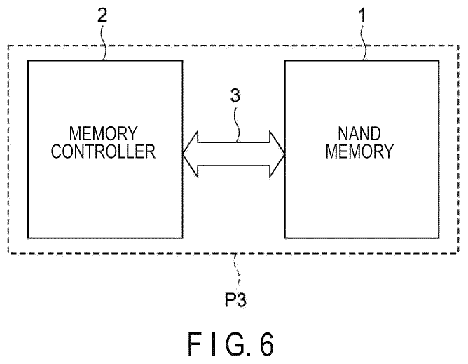

FIG. 6 is a schematic diagram showing a configuration of a memory system according to a third embodiment.

The memory system of the present embodiment (FIG. 6) has the similar configuration to that of the memory system of the first embodiment (FIG. 3). It is noted, however, that the NAND memory 1 and the memory controller 2 of the present embodiment are included in the same semiconductor package P3. Notably, the NAND memory 1 of the present embodiment may have the similar configuration to that of the NAND memory 1 of the first embodiment, or may have the similar configuration to that of the NAND memory 1 of the second embodiment.

According to the present embodiment, as with the first and second embodiments, preferable temperature control for the NAND memory 1 can be realized.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor device that is operable based on a signal from an external device, the semiconductor device comprising, on a chip:
a memory cell array;
a temperature sensor configured to detect a temperature in the semiconductor device; and
a temperature control circuit configured to control signal processing for operating the memory cell array so as to reduce heat generation by the semiconductor device based on the temperature detected by the temperature sensor.

2. The semiconductor device according to claim 1, further comprising, on the chip:
a first register, wherein
the temperature control circuit is configured to turn into an enabled state during which control of the signal processing to reduce the heat generation is performed, when the temperature detected by the temperature sensor is higher than a first temperature set in the first register.

3. The semiconductor device according to claim 2, further comprising, on the chip:
a first comparator configured to output a first signal indicating a comparison result between the temperature detected by the temperature sensor and the first temperature, wherein
the temperature control circuit turns into the enabled state when the first signal indicates that the temperature detected by the temperature sensor is higher than the first setting temperature.

4. The semiconductor device according to claim 2, further comprising, on the chip:
a second register, wherein
the temperature control circuit is configured to turn into an disabled state during which control of the signal processing to reduce the heat generation is not performed, when the temperature detected by the temperature sensor is lower than a second temperature set in the second register after the temperature control circuit turns into the enabled state.

5. The semiconductor device according to claim 4, further comprising, on the chip:
a second comparator configured to output a second signal indicating a comparison result between the temperature detected by the temperature sensor and the second temperature, wherein
the temperature control circuit is configured to turn into the disabled state when the second signal indicates that the temperature detected by the temperature sensor is lower than the second temperature after the temperature control circuit turns into the enabled state.

6. The semiconductor device according to claim 4, wherein the second temperature is lower than the first temperature.

7. The semiconductor device according to claim 1, further comprising, on the chip:
a first register;
a second register; and
a comparator configured to output a first signal indicating a comparison result between the temperature detected by the temperature sensor and a first temperature set in the first register, and output a second signal indicating a comparison result between the temperature detected by the temperature sensor and a second temperature set in the second register, wherein
the temperature control circuit is configured to:
turn into an enabled state during which control of the signal processing to reduce the heat generation is performed, when the first signal indicates that the temperature detected by the temperature sensor is higher than the first temperature, and
turn into a disabled state during which the control of the signal processing to reduce the heat generation is not performed, when the second signal indicates that the temperature detected by the temperature sensor is lower than the second temperature after the temperature control circuit is turned into the enabled state.

8. The semiconductor device according to claim 1, wherein control of the signal processing to reduce the heat generation performed by the temperature control circuit includes control of a frequency of a clock signal in the semiconductor device.

9. The semiconductor device according to claim 8, wherein the control of the frequency of the clock signal in the semiconductor device includes reducing the frequency of the clock signal.

10. The semiconductor device according to claim 1, wherein control of the signal processing to reduce the heat generation performed by the temperature control circuit controls includes control of a timing of switching a state of the semiconductor device from a busy state to a ready state.

11. The semiconductor device according to claim 10, wherein the control of the timing of switching a state of the semiconductor device includes delaying the timing.

12. The semiconductor device according to claim 1, wherein control of the signal processing to reduce the heat generation performed by the temperature control circuit includes control of a timing of storing information indicating a ready state of the semiconductor device in a register.

13. The semiconductor device according to claim 12, wherein the control of the timing of storing the ready state of the semiconductor device includes delaying the timing.

14. The semiconductor device according to claim 1, wherein control of the signal processing to reduce the heat generation performed by the temperature control circuit includes control a communication speed on a bus of the semiconductor device.

15. The semiconductor device according to claim 14, wherein the control of the communication speed on the bus includes reducing the communication speed on the bus.

16. The semiconductor device according to claim 1, wherein control of the signal processing to reduce the heat generation performed by the temperature control circuit includes a first control of a frequency of a clock signal in the semiconductor device, a second control of a timing of switching a state of the semiconductor device from a busy state to a ready state, and a third control a communication speed on a bus of the semiconductor device.

17. The semiconductor device according to claim 16, wherein the temperature control circuit is configured to selectively perform one or two, but not all, of the first, second, and third controls depending on an operational state of the memory cell array.

18. The semiconductor device according to claim 1, wherein the semiconductor device is a semiconductor memory, and the external device is a memory controller that controls an operation of the semiconductor memory.

19. The semiconductor device according to claim 1, wherein the external device is included in a package different from a package including the semiconductor device.

20. A control method of a semiconductor device that is operable based on a signal from an external device and includes a memory cell array, a temperature sensor, and a temperature control circuit on a chip, the control method comprising:
detecting a temperature in the semiconductor device with the temperature sensor; and
controlling, with the temperature control circuit, signal processing for operating the memory cell array so as to reduce heat generation by the semiconductor device based on the detected temperature.
